(19) United States
(12) Patent Application Publication
(10) Pub. No.: US 2006/0067122 A1
(43) Pub. Date: Mar. 30, 2006

(54) Charge-trapping memory cell

(76) Inventor: Martin Verhoeven, Radebeul (DE)

Correspondence Address: SLATER & MATSIL LLP, 17950 PRESTON ROAD, SUITE 1000, DALLAS, TX, 75252, US

(21) Appl. No.: 10/952,711

(22) Filed: Sep. 29, 2004

(51) Int. Cl. G11C 11/34; G11C 16/04

(52) U.S. Cl. 365/185.05

(57) ABSTRACT

The channel region is slightly elevated with respect to the source and drain regions to form steps in the semiconductor surface, which are covered by a dielectric memory layer sequence provided for charge-trapping, the memory layer sequence comprising a lower confinement layer, a memory layer and an upper confinement layer. Electrons that are accelerated from source to drain are more probably scattered on a straight trajectory, on which they pass the lower confinement layer and are trapped in the memory layer. This memory cell aims at improving the speed of write operations.

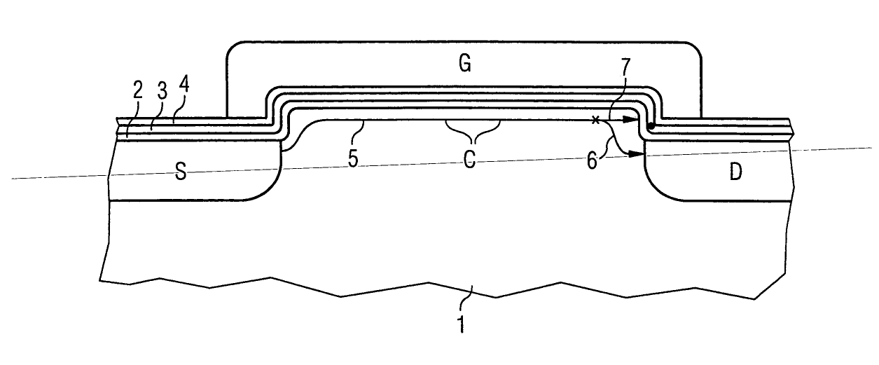

### TECHNICAL FIELD

The present invention concerns charge-trapping memory cells, especially memory cells of the SONOS or NROM type.

### BACKGROUND

Non-volatile memory cells that are electrically programmable and erasable can be realized as charge-trapping memory cells which comprise a memory layer sequence of dielectric materials with a memory layer between confinement layers of dielectric material having a larger energy band gap than the memory layer. This memory layer sequence is arranged between a channel region within a semiconductor layer or substrate and a gate electrode, which is provided to control the channel by means of an applied electric voltage. The programming of the cell is performed by the acceleration of charge carriers, especially electrons, in the channel region to generate charge carriers of sufficient kinetic energy to penetrate the confinement layer and to be trapped in the memory layer. Source and drain regions are provided at both ends of the channel region to apply the accelerating electric voltage.

The threshold voltage of the transistor structure is sensed when the programmed state of the memory cell is read. It is possible to store bits at both channel ends by the application of reverse operating voltages. This means that two bits can be programmed in each charge-trapping memory cell. Examples of charge-trapping memory cells are the SONOS memory cells, in which each confinement layer is an oxide of the semiconductor material and the memory layer is a nitride of the semiconductor material, usually silicon.

The memory layer can be substituted with another dielectric material, provided the energy band gap is smaller than the energy band gap of the confinement layers. The difference in the energy band gaps should be as great as possible to secure a good charge carrier confinement and thus a good data retention. When using silicon dioxide as confinement layers, the memory layer may be tantalum oxide, cadmium silicate, titanium oxide, zirconium oxide or aluminum oxide. Also intrinsically conducting (non-doped) silicon may be used as the material of the memory layer.

A publication by B. Eitan et al., “NROM: a Novel Localized Trapping, 2-Bit Nonvolatile Memory Cell” in IEEE Electron Device Letters, volume 21, pages 543 to 545 (2000), which is incorporated herein by reference, describes a charge-trapping memory cell with a memory layer sequence of oxide, nitride and oxide which is especially adapted to be operated with a reading voltage that is reverse to the programming voltage (reverse read). The oxide-nitride-oxide layer sequence is especially designed to avoid the direct tunneling regime and to guarantee the vertical retention of the trapped charge carriers. The oxide layers are specified to have a thickness of more than 5 nm.

A preferred method to program a charge-trapping memory cell is channel hot electron (CHE) injection, which means that electrons moving through the channel and being accelerated by a voltage that is applied between source and drain acquire enough kinetic energy to be able to penetrate the lower confinement layer of the memory layer sequence arranged between the channel region and the gate electrode. In ordinary memory cell structures, the efficiency of this programming process is low because the electrons have to be scattered in a direction perpendicular with respect to the straight trajectory between source and drain, which is most likely, as the drain region, lying on a positive electric potential as compared to the source region and therefore attracting the electrons, is located in a straight longitudinal extension of the channel. The memory layer sequence is arranged above the semiconductor material between the semiconductor body and the gate electrode. Therefore, the electrons have to be scattered upwards to be injected into the memory layer or trapping layer by the interference of scattering impurities in the semiconductor material.

### SUMMARY OF THE INVENTION

In one aspect, the present invention improves the low write efficiency of charge-trapping memory cells, especially of NROM memory cells.

In a further aspect, the invention speeds up the programming operation of the memory cell.

In still a further aspect, the invention discloses how to achieve these objects within the frame of standard production methods.

In a first embodiment, a charge-trapping memory cell includes a semiconductor layer or substrate with a main surface. A source region, a channel region and a drain region are arranged in succession at the main surface. The source region and the drain region are doped to have the same conductivity type. A memory layer sequence of dielectric materials is provided for charge-trapping and includes a lower confinement layer, a memory layer and an upper confinement layer. The memory layer sequence is arranged on the main surface at least in areas that cover junctions of the source region and the drain region facing the channel region. A gate electrode is arranged on the memory layer sequence and provided to control the channel. The main surface is structured so that a plane formed by the main surface in the area of the channel region intersects the memory layer sequence.

In a second embodiment, a charge-trapping memory cell includes a semiconductor layer or substrate with a main surface. A source region, a channel region and a drain region are arranged at the main surface. A memory layer sequence of dielectric materials is provided for charge-trapping. The memory layer sequence includes a lower confinement layer, a memory layer and an upper confinement layer. The memory layer sequence is arranged at least adjacent to junctions between the source region and the channel region and between the drain region and the channel region. A gate electrode is arranged above the channel region and electrically insulated from the semiconductor layer or substrate. The source region and the drain region are slightly recessed with respect to the channel region. The memory layer sequence is arranged at both ends of the channel region with respect to a longitudinal direction extending from source to drain.

In a third embodiment, a method of forming a charge-trapping memory cell includes providing a semiconductor body. A channel region is formed at a main surface of the semiconductor body. Source and drain regions are formed in the semiconductor body adjacent the channel region such that the source region is spaced from the drain region by the channel region. An upper surface of the channel region is located in a plane that is laterally elevated relative to a plane of an upper surface of the source and drain regions. A memory layer sequence overlies the channel region and at least portions of the source and drain regions adjacent the channel region. The memory layer sequence includes a lower confinement layer, a memory layer and an upper confinement layer. A gate is formed over the memory layer sequence.

A fourth embodiment provides a method of operating a semiconductor device. A semiconductor body with a substantially planar upper surface is provided. Carriers are caused to travel through the semiconductor body in a direction substantially parallel to the upper surface. The carriers continue to travel in the direction substantially parallel to the upper surface so that the carriers travel through a sidewall of the semiconductor body, through a confinement layer and into a memory storage layer.

These and other features and advantages of the invention will become apparent from the following brief description of the drawings, detailed description and appended claims and drawings.

### BRIEF DESCRIPTION OF THE DRAWINGS

The appended figure shows a cross-section of a preferred example of the charge-trapping memory cell according to this invention.

The following list of reference symbols can be used in conjunction with the figures:

1 substrate

2 lower confinement layer

3 memory layer

4 upper confinement layer

5 electron trajectory

6 first path

7 second path

C channel region

D drain region

G gate eletrode

S source region

### DETAILED DESCRIPTION OF ILLUSTRATIVE EMBODIMENTS

The preferred embodiment will now be described with respect to the figure. In this embodiment, a charge-trapping memory cell comprises an arrangement of source, channel and drain regions at a main surface of a semiconductor layer or substrate in such a way that the source and drain regions are slightly recessed with respect to the major part of the channel region. At least a section of the memory layer sequence is arranged across the straight longitudinal extension of the channel. This geometry enables more efficient injection of electrons into the memory layer by forward scattering. This will translate into shorter write times and higher speed of operation of the memory cell.

The figure shows a cross-section of a preferred embodiment of the inventive memory cell. A semiconductor body 1, e.g., a layer or substrate, is provided with regions of source S, channel C and drain D at a main surface. The regions of source S and drain D are formed in semiconductor material as doped regions of the same type of conductivity. The substrate 1 is preferably provided with a low basic doping of opposite conductivity type. The channel region C is controlled by a gate electrode G that is arranged above the channel region and electrically insulated from the semiconductor material by dielectric material.

This dielectric material comprises the storage means, which is preferably a memory layer sequence comprising a lower confinement layer 2, a memory layer 3, and an upper confinement layer 4. As the charge-trapping takes place in the vicinity of the drain junction, i.e. the boundary of the drain region that faces the channel region, it is sufficient, if the memory layer sequence is provided at least above the drain junction at the end of the channel.

Two bits of information can be stored in the charge-trapping memory cell by reversing the applied acceleration voltage between source and drain. Therefore, it is preferred to have the memory layer sequence also adjacent to the source junction facing the channel region. A sufficient electric insulation of the gate electrode from the semiconductor material can be obtained by a single dielectric layer in the regions where no charge-trapping takes place. In the described embodiment, the memory layer sequence is applied all over the channel region and at least part of the source and drain regions. The embodiments of the inventive memory cell can be varied to incorporate additional features according to the charge-trapping memory cells known from prior art.

It is one feature of the preferred embodiment memory cell that the main surface of the semiconductor layer or substrate 1 is structured so that a plane formed by the main surface in the area of the channel region C intersects the memory layer sequence. This is achieved by an elevation of the channel region, which forms steps at the source region and at the drain region. The steps are covered by the memory layer sequence in such a manner that there are at least sections of the memory layer sequence that directly adjoin the channel region so that electrons can be injected into the memory layer when moving on a straight trajectory. This is facilitated by the presence of vertical sections of the memory layer sequence that cross the straight longitudinal extension of the channel direction, which can be clearly seen from the figure.

The electron trajectory passes the channel region C slightly beneath the gate dielectric. The electrons are accelerated towards the drain region D, which they enter following the first possible path 6 indicated in the figure. The deviation of the first path 6 from the straight line is due to the attracting potential of the drain region D. If the electrons are scattered by impurities in the semiconductor material at the position marked with a cross in the figure, they will most probably follow a second path 7, which is the forward direction on an substantially straight line. In this case, the electrons hit the lower confinement layer, which they can penetrate due to the acquired high kinetic energy so that the electrons are trapped in the memory layer 3 at the position marked with the black dot. This section of the memory layer sequence is located at the vertical flank of the step formed by the elevated channel region.

The preferred embodiment structure of the charge-trapping memory cell thus provides an arrangement of the regions of source, channel and drain which results in an electron trajectory that is curved both in the proximity of the source region and in the proximity of the drain region. The inertia of the accelerated electrons is favorable for a straight movement into the memory layer sequence. This will facilitate and speed up the programming process during a write operation. The symmetric structure enables the programming of bits at source and drain. The elevation of the main surface in the area of the channel region or, equivalently, the slightly recessed source and drain regions bring about a significant improvement of the write efficiency of the charge-trapping memory cell.

Although the present invention and its advantages have been described in detail, it should be understood that various changes, substitutions and alterations can be made herein without departing from the spirit and scope of the invention as defined by the appended claims.

What is claimed is:

1. A charge-trapping memory cell, comprising:
a semiconductor body with a main surface;
a source region, a channel region and a drain region disposed at the main surface, the source region being spaced from the drain region by the channel region, wherein the source region and the drain region are doped to have the same conductivity type;
a memory layer sequence of dielectric materials provided for charge-trapping and comprising a lower confinement layer, a memory layer and an upper confinement layer, the memory layer sequence being arranged on the main surface at least in areas that cover junctions between the source region and the channel region and between the drain region and the channel region, wherein main surface is structured so that a plane formed by the main surface in the area of the channel region intersects the memory layer sequence; and
a gate electrode arranged adjacent the memory layer sequence and provided to control the channel.

2. The charge-trapping memory cell as claimed in claim 1, wherein:
the main surface is elevated at a region of the channel region thereby forming a first step at the junction between the source region and the channel region and a second step at the junction between the drain region and the channel region;
the first and second steps are covered by the memory layer sequence; and
the channel region is substantially coplanar with the memory layer sequence at the steps.

3. The charge-trapping memory cell as claimed in claim 1, wherein the memory layer sequence comprises sections that extend perpendicularly to a longitudinal channel direction from source to drain.

4. The charge-trapping memory cell as claimed in claim 1, wherein the upper and lower confinement layers comprise oxide layers and the memory layer comprises a nitride layer.

5. The charge-trapping memory cell as claimed in claim 1, wherein the semiconductor body comprises a semiconductor substrate.

6. The charge-trapping memory cell as claimed in claim 1, wherein the semiconductor body comprises a semiconductor layer.

7. A charge-trapping memory cell, comprising:
a semiconductor body with a main surface;
a source region, a channel region and a drain region arranged at the main surface;
a memory layer sequence of dielectric materials provided for charge-trapping, the memory layer sequence comprising a lower confinement layer, a memory layer and an upper confinement layer;
wherein the memory layer sequence is arranged at least adjacent to junctions between the source region and the channel region and between the drain region and the channel region;
a gate electrode being arranged above the channel region and electrically insulated from the semiconductor body; and
wherein the source region and the drain region are slightly recessed with respect to the channel region, the memory layer sequence being arranged at both ends of the channel region with respect to a longitudinal direction extending from source to drain.

8. The charge-trapping memory cell as claimed in claim 7, wherein the channel region and the recessed source and drain regions form steps in the main surface and wherein the steps are covered with the memory layer sequence.

9. The charge-trapping memory cell as claimed in claim 8, wherein the gate electrode covers the channel region and the steps in the main surface.

10. The charge-trapping memory cell as claimed in claim 9, wherein the gate electrode covers the channel region and at least areas of the source region and the drain region.

11. The charge-trapping memory cell as claimed in claim 7, wherein the gate electrode covers the channel region and at least areas of the source region and the drain region.

12. The charge-trapping memory cell as claimed in claim 7, wherein the upper and lower confinement layers comprise oxide layers and the memory layer comprises a nitride layer.

13. A method of forming a charge-trapping memory cell, the method comprising:
providing a semiconductor body;
forming a channel region at a main surface of the semiconductor body;
forming source and drain regions in the semiconductor body adjacent the channel region such that the source region is spaced from the drain region by the channel region, wherein an upper surface of the channel region is located in a plane that is laterally elevated relative to a plane of an upper surface of the source and drain regions;
forming a memory layer sequence overlying the channel region and at least portions of the source and drain regions adjacent the channel region, the memory layer sequence including a lower confinement layer, a memory layer and an upper confinement layer; and
forming a gate overlying the memory layer sequence.

14. The method of claim 13 wherein a junction between the source region and the channel region is located at a first step and wherein a junction between the source region and the channel region is located at a second step, and wherein the memory layer sequence overlies the first step and the second step.

15. The method of claim 14 wherein the first step comprises a vertical sidewall of the semiconductor body and wherein the second step comprises a vertical sidewall of the semiconductor body.

16. A method of operating a semiconductor device, the method comprising:
providing a semiconductor body with a substantially planar upper surface;
causing carriers to travel through the semiconductor body in a direction substantially parallel to the upper surface; and
causing the carriers to continue travelling in the direction substantially parallel to the upper surface so that the carriers travel through a sidewall of the semiconductor body, through a confinement layer and into a memory storage layer.

17. The method of claim 16 wherein the carriers comprise electrons.

18. The method of claim 16 wherein the carriers are caused to travel through a sidewall that is substantially perpendicular to the upper surface.

19. The method of claim 16 wherein causing the carriers to travel and causing the carriers to continue travelling comprises causing the carriers to travel in a substantially straight line.

20. The method of claim 16 wherein the confinement layer and memory storage layer comprise dielectric layers.
